(19) United States
(12) Patent Application Publication
(10) Pub. No.: US 2025/0287753 A1
(43) Pub. Date: Sep. 11, 2025

(54) VERTICALLY-LAMINATED MICRODISPLAY PANEL REQUIRING NO COLOR FILTER AND MANUFACTURING METHOD THEREOF

(71) Applicant: WAVELORD CO., LTD, Hwaseong-si (KR)

(72) Inventors: Juneo SONG, Suwon-si (KR); Ji Hyung MOON, Gunpo-si (KR)

(73) Assignee: WAVELORD CO., LTD, Hwaseong-si (KR)

(21) Appl. No.: 18/860,666

(22) PCT Filed: Mar. 12, 2024
(86) PCT No.: PCT/KR2024/003155

§ 371 Date: Oct. 27, 2024

(30) Foreign Application Priority Data
Mar. 13, 2023 (KR) 10-2023-0032710
Aug. 23, 2023 (KR) 10-2023-0110618

(51) Int. Cl. H10H 29/34; H10H 29/01; H10H 29/856

(52) U.S. Cl. CPC H10H 29/34; H10H 29/012; H10H 29/856

(57) ABSTRACT

The present invention relates to a vertically-laminated microdisplay panel requiring no color filter, the panel comprising: a back wafer, the top surface of which has multiple CMOS electrode pads aligned thereon; multiple LED laminates, each of which includes multiple light emitting units and multiple bonding layers vertically laminated on the back wafer, and which are aligned on the multiple CMOS electrode pads, respectively; and a common electrode formed on the multiple LED laminates, wherein each of the multiple LED laminates emits only a particular color by blocking the light generated from at least one light emitting unit among the multiple light emitting units, or having a short passage formed through at least one light emitting unit among the multiple light emitting units to bypass current so as to prevent the current from being injected into the light emitting unit.

### TECHNICAL FIELD

The present invention relates to a vertically-laminated microdisplay panel that does not require a color filter, and a method of manufacturing the same, and more specifically, to a vertically stacked light-emitting diode-on-silicon (LEDoS) microdisplay panel which eliminates the need for a process of arranging a light-emitting diode (LED) stack and a complementary metal oxide semiconductor (CMOS) electrode pad by using an engineering monolithic epitaxy wafer when a front wafer and a back wafer are bonded and simultaneously eliminates the need for a color filter due to each LED stack being able to emit only light of a specific color, and a method of manufacturing the same.

### BACKGROUND ART

The types of implementation of the metaverse, which has recently been attracting attention, are classified into four types of virtual reality (VR), augmented reality (AR), mixed reality (MR), and extended reality (XR). Among these, it is expected that a metaverse ecosystem will be developed in the future centered on XR that is a reality in which VR, AR and MR are combined. In order to effectively implement XR, there is a need for devices (for example, smart glasses or head-mounted displays) that include microdisplays with a diagonal length of less than 1 inch as a core component, along with software for next-generation computing platforms that can provide innovative user experiences. In particular, the development of high-performance microdisplay panel technologies is absolutely required to provide the greatest immersion, visibility, and convenience to XR users and minimize dizziness.

As illustrated in FIG. 1, a microdisplay panel 10 of the related art is a technology in which a Si complementary metal oxide semiconductor (CMOS) semiconductor wafer process is combined with a high-resolution, high-luminance, and ultra-small display process. The microdisplay panel 10 of the related art may have a structure in which a Si CMOS wafer 11, which has a size of 4″ or more and a (100) crystal plane and includes a plurality of CMOS electrode pads 12, is bonded to a transparent wafer 13, which has a size of less than 4″ and includes a micro-light-emitting diode (LED) electrode pad 14 and a plurality of micro-LED chips 15, through a conductive bonding portion 16. Meanwhile, the types of microdisplay panels expected to be applied to XR devices include liquid crystal (LC)-based LC on Si (LCoS) panels, organic light-emitting diode (OLED)-based OLED on Si (OLEDoS) panels, and ultra-small micro-LED-based LED on Si (LEDoS) panels with a pixel size of less than 5 μm. VR devices to which low-pixel density displays are applied are being developed and mass-produced around LCOS and OLEDOS panels.

However, with the development of metaverse implementation technologies, there is an increasing need for lightweight AR, MR, and XR devices to which high-pixel density microdisplay panels are applied. In order to satisfy this need, there is an urgent need to develop an LEDOS technology which is considered to be an ideal solution in theory based on the superior properties of inorganic materials, but a microdisplay panel platform therefor has not yet been established.

LEDOS based on ultra-small micro-LEDs with a pixel size of less than 5 μm has advantages of an excellent power-to-performance ratio and a short response speed when applied to XR devices and has advantages in that inorganic materials are used to have a long lifespan, power is efficiently used to reduce heat generation, and a battery is usable for the long term. In particular, since XR devices have a very short distance between a display and the eyes, even a little time delay in image conversion may easily cause discomfort such as dizziness. Therefore, LEDOS which has a nanosecond response speed is considered to be the most suitable for XR devices as compared to LCOS and OLEDOS which have a microsecond response speed.

Furthermore, it is evaluated that the biggest reason why LEDOS is attracting attention in AR, MR, and XR devices unlike in VR is due to luminance and luminous efficiency. Due to the characteristics of smart glasses that can be worn regardless of location, high brightness is an essential condition for normal operation even in outdoor environments such as sunlight, and in theory, micro-LEDs supports a luminance of tens to millions of nits, and while OLEDs are organic, micro-LEDs are inorganic and thus also have an advantage of high luminous efficiency.

However, despite the above-described advantages, the biggest reason why LEDOS based on ultra-small micro-LEDs with a pixel size of less than 5 μm are not used as a major component of XR devices is that LEDoS is difficult to mass-produce. That is, in LEDOS, since millions of ultra-small micro-LEDs should be fixed onto a Si CMOS wafer, the process difficulty is high and the yield is very low, which leads to an increase in manufacturing costs to generate a high component price. Thus, the high component price is reflected in the final consumer price, and the LEDOS is supplied as a high-priced XR device, which makes it difficult to meet market demand.

Meanwhile, as shown in FIG. 2, up to now, LEDOS using a Group III-V compound (GaN, GaP, or the like) micro-LED light source has been developed through traditional approaches such as \textcircled{1} monolithic integration of a wafer (or a unit die) consisting of micro-LED arrays on a Si CMOS wafer or \textcircled{2} hybridization between wafers (or unit dies) on a blue, green, or red light source wafer (or a unit die) on which Si CMOS wafers or micro-LED arrays are manufactured.

Up to now, one of the biggest obstacles to the development of LEDOS using blue, green, and red micro-LED light sources consisting of Group III-V compounds is that it is not easy to secure a solution for pixels having a size of less than 5 μm. Recently, 5 μm level pixels have been successfully demonstrated using monolithic integration technologies, and some product demonstrations developed based on hybridization technologies have been manufactured using sapphire flip chips to achieve 10 μm level pixels. In addition, it has been demonstrated that it is possible to reduce pixels on a 5 μm level in the same way by using micro tube interconnections in hybridization technologies. However, both monolithic integration and hybridization technologies are impractical solutions with significant difficulties in mass production in terms of quality and yield and have a problem in that mass production is difficult.

The above-described monolithic integration technology and hybrid technology have the common characteristics in which a front plane wafer consisting of Group III-V compound micro-LED arrays and a Si CMOS back plane wafer consisting of a number of IC electrode pad arrays are each separately designed and manufactured and then assembled. Since micro-LED arrays manufactured at unit die-level or wafer-level on Si CMOS wafers should be arranged ultra-finely in any way, in this case, the arrangement is limited by the precision of a process-related device, which seriously affects pixels and pixel to pixel distance (pitch) limitations and causes a problem that mass production is also difficult. Accordingly, in order to manufacture LEDoS to which blue, green, and red micro-LED light sources which have high resolution and high luminance, are driven at a high speed, include pixels with a size of less than 5 μm, and have a pitch of less than 3 μm, are applied, there is a need for new alternative solutions that can solve the above-described ultra-fine arrangement constraints.

Accordingly, although several impressive product demonstrations, which include 6 μm pixels using engineering monolithic epitaxy wafers manufactured through a low-temperature metal bonding process between a Si CMOS wafer and a micro-LED array wafer, have been recently released, mass production is considered impossible due to low quality and yield issues caused by low-temperature metal bonding and the use of wafers with a small diameter of 6 inches or less. Above all, when ultra-fine pixels with a size of less than 3 μm for microdisplays are manufactured using conventional engineering monolithic epitaxy wafers through metal bonding, a patterning etching process faces even greater difficulties.

As another example, a novel engineering monolithic epitaxy wafer approach, which has made significant progress in solving a problem of a limitation on the brightness and resolution of LEDOS with Group III-V compound micro-LED light sources and simultaneously is capable of providing mass production and low-cost manufacturing solutions through the use of 12-inch diameter Si CMOS wafers, has been proposed. As shown in FIG. 3, specifically, in the corresponding technology, a process using an engineering monolithic epitaxy wafer is performed through the following four operations: \textcircled{1} an LED epitaxy cut to a final microdisplay panel 100 size (4 mm×6 mm) is arranged and bonded onto a 12 inch Si blank wafer at a unit die level, and an LED growth wafer and a buffer layer are removed to perform planarization and leave only a 1.5 μm thick LED active layer on the large diameter Si blank wafer, \textcircled{2} the LED active layer left on the Si blank wafer is bonded to a Si CMOS wafer through multilayer metal bonding at a wafer level, \textcircled{3} the 12 inch Si blank wafer is removed, and then \textcircled{4} a micro-LED array that serves as a pixel is directly patterned on a Si CMOS wafer and manufactured.

However, in operation \textcircled{1}, when an LED epitaxy die is bonded onto the Si blank wafer, there is a limitation in that the die should be bonded by arranging a position on a Si CMOS integrated circuit (IC) wafer with the same size, in operation \textcircled{2}, when the LED active layer is bonded with multilayer metals including low-melting-point metals (Sn and In), there is a problem in that a discharge phenomenon in which low-melting-point metal components overflow relatively easily occurs to cause short circuit defects in which micro-LED sub-pixel arrays in a panel are electrically connected to each other or are connected to neighboring CMOS IC electrode pad arrays adjacent thereto, and in operation \textcircled{4}, there is a problem in that accurate ultra-fine patterning is difficult due to an opaque multilayer metal bonding layer, and defects are caused by the re-deposition of multilayer metal layer byproducts generated in a plasma dry process.

That is, the engineering monolithic epitaxy wafer approach presented in the above-described technologies is evaluated as a solution that is a step closer to implementing LEDoS based on ultra-small micro-LEDs with a pixel size of less than 5 μm. However, there are quality and yield issues due to the use of metals (low temperature, multilayer) in wafer bonding, it is very difficult to manufacture high-resolution microdisplays including ultra-fine pixels with a size of less than 3 μm, and there are also problems according to some arrangement processes. Thus, a new alternative is needed for this.

Furthermore, since a color filter is still applied to a vertically stacked tandem structure of conventional microdisplays to implement a full color, there are disadvantages in terms of color quality, process complexity, and productivity.

### DISCLOSURE

### Technical Problem

The present invention is directed to solving the above-described conventional problems and providing a vertically stacked light-emitting diode-on-silicon (LEDoS) microdisplay panel which eliminates the need for a process of arranging a light-emitting diode (LED) stack and a complementary metal oxide semiconductor (CMOS) electrode pad by using an engineering monolithic epitaxy wafer when a front wafer and a back wafer are bonded and simultaneously eliminates the need for a color filter due to each LED stack being able to emit only light of a specific color, and a method of manufacturing the same.

### Technical Solution

According to the present invention, the above object is achieved by a vertically-laminated microdisplay panel that does not require a color filter, which includes a back wafer having an upper surface on which a plurality of complementary metal oxide semiconductor (CMOS) electrode pads are arranged, a plurality of light-emitting diode (LED) stacks of which a plurality of light-emitting portions and a plurality of bonding layers are vertically stacked on the back wafer and which are arranged on the plurality of CMOS electrode pads, and a common electrode formed on the plurality of LED stacks, wherein each of the plurality of LED stacks emits only light of a specific color by blocking light generated from at least one light-emitting portion of the plurality of light-emitting portions or forming a short path in at least one light-emitting portion of the plurality of light-emitting portions so that a current does not flow into and bypasses the light-emitting portion.

In addition, the plurality of LED stacks may include a first LED stack configured to emit only light having a first color, a second LED stack configured to emit only light having a second color, and a third LED stack configured to emit only light having a third color, and each of the first LED stack, the second LED stack, and the third LED stack may include a first light-emitting portion bonded onto the CMOS electrode pad through a first bonding layer to emit light having the first color, a second light-emitting portion bonded onto the first light-emitting portion through a second bonding layer to emit light having the second color, and a third light-emitting portion bonded onto the second light-emitting portion through a third bonding layer to emit light having the third color.

In addition, the first LED stack may emit only the light having the first color by forming the short path to pass through the third light-emitting portion and the second light-emitting portion so that a current does not flow into and bypasses the third light-emitting portion and the second light-emitting portion, the second LED stack may emit only the light having the second color by forming the short path to pass through the third light-emitting portion so that a current does not flow into and bypasses the third light-emitting portion and blocking light generated from the first light-emitting portion, and the third LED stack may emit only the light having the third color by blocking light generated from the second light-emitting portion and the first light-emitting portion.

In addition, the second LED stack may block the light generated from the first light-emitting portion through a metal layer formed on the first light-emitting portion, and the third LED stack may block the light generated from the second light-emitting portion and the first light-emitting portion through the metal layer formed on each of the second light-emitting portion and the first light-emitting portion.

In addition, the metal layer includes a lower layer which has an absorptive property to block light generated from below and an upper layer which has a reflective property to reflect light generated from above.

In addition, the short path may be formed of a material that is electrically conductive.

In addition, the bonding layer may be formed of a ceramic material that is optically transparent and electrically conductive.

In addition, the back wafer may be a silicon (Si) wafer.

In addition, an ohmic contact electrode may be formed on at least one of an upper surface and a lower surface of each of the light-emitting portions.

In addition, the ohmic contact electrode may be formed of a material that is optically transparent and electrically conductive.

According to the present invention, the above object is achieved by a method of manufacturing a vertically-laminated microdisplay panel that does not require a color filter, which includes a preparing operation of preparing a plurality of front wafers which include a support wafer and a light-emitting portion and emit light having different colors, and preparing a back wafer having an upper surface on which a plurality of complementary CMOS electrode pads are arranged, a stacking operation of repeating a process of bonding the front wafer onto the back wafer through bonding layers and then removing the support wafer and vertically stacking the plurality of light-emitting portions and the bonding layers on the back wafer, an etching operation of etching the plurality of stacked light-emitting portions and bonding layers to be divided into preset units and arranging a plurality of LED stacks on the plurality of CMOS electrode pads, and a forming operation of forming a common electrode on the plurality of LED stacks, wherein each of the plurality of LED stacks emits only light of a specific color by blocking light generated from at least one light-emitting portion of the plurality of light-emitting portions or forming a short path in at least one light-emitting portion of the plurality of light-emitting portions so that a current does not flow into and bypasses the light-emitting portion.

In addition, the plurality of front wafers may include a first front wafer including the support wafer and a first light-emitting portion, a second front wafer including the support wafer and a second light-emitting portion, and a third front wafer including the support wafer and a third light-emitting portion, and the plurality of LED stacks may include a first LED stack configured to emit light having only a first color, a second LED stack configured to emit light having only a second color, and a third LED stack configured to emit light having only a third color.

In addition, the stacking operation may include a first stacking operation of bonding the first front wafer onto the back wafer through a first bonding layer and then removing the support wafer to stack the first light-emitting portion on the back wafer, a second stacking operation of bonding the second front wafer onto the first light-emitting portion through a second bonding layer and then removing the support wafer to stack the second light-emitting portion on the first light-emitting portion, and a third stacking operation of bonding the third front wafer onto the second light-emitting portion through a third bonding layer and then removing the support wafer to stack the third light-emitting portion on the second light-emitting portion.

In addition, in the first stacking operation, after the support wafer is removed, a metal layer may be formed on a portion of the first light-emitting portion, in the second stacking operation, after the support wafer is removed, the metal layer may be formed on a portion of the second light-emitting portion, the second LED stack may block light generated from the first light-emitting portion through the metal layer formed on the first light-emitting portion, and the third LED stack may block light generated from the second light-emitting portion and the first light-emitting portion through the metal layer formed on each of the second light-emitting portion and the first light-emitting portion.

In addition, the metal layer may include a lower layer which has an absorptive property to block light generated from below and an upper layer which has a reflective property to reflect light generated from above.

In addition, in the etching operation, the short path may be formed to pass through the third light-emitting portion and the second light-emitting portion at a portion in which the first LED stack is formed, and the short path may be formed to pass through the third light-emitting portion at a portion in which the second LED stack is formed. In the first LED stack, a current may not flow into and bypass the third light-emitting portion and the second light-emitting portion through the short path, and in the second LED stack, a current may not flow into and bypasses the third light-emitting portion through the short path.

In addition, the short path may be formed of a material that is electrically conductive.

In addition, the bonding layer may be formed of a ceramic material that is optically transparent and electrically conductive.

In addition, the support wafer and the back wafer may be silicon (Si) wafers.

In addition, an ohmic contact electrode may be formed on at least one of an upper surface and a lower surface of each of the light-emitting portions.

In addition, the ohmic contact electrode may be formed of a material that is optically transparent and electrically conductive.

### Advantageous Effects

According to the present invention, since a color filter is unnecessary despite the adoption of a vertically stacked tandem structure, the color quality of a microdisplay can be considerably improved, and process complexity and productivity can be considerably improved.

In addition, according to the present invention, unlike conventional monolithic integration methods or hybrid methods in which arrangement issues are present, since a stack on an engineering monolithic epitaxy wafer is etched and divided into preset units to allow a plurality of light-emitting diode (LED) stacks to be arranged on a plurality of complementary metal oxide semiconductor (CMOS) electrode pads, not only wafers with a small diameter of 6 inches or less, but also wafers with a large diameter of 8 inches or more can be used, which has the effect of considerably increasing the yield of products.

In addition, according to the present invention, since a ceramic material rather than metal is used for a bonding layer and an ohmic contact electrode, there are effects of considerably reducing the possibility of electrical short circuit detects and considerably increasing the reliability of a device. In addition, a plasma dry process of arranging an LED stack has effects in which etching is easy, and simultaneously the problem of re-deposition of etch by-products does not occur. Moreover, the above-described ease of etching provides an advantage in that it is much more advantageous for manufacturing high-resolution microdisplays including ultra-fine pixels with a size of less than 3 μm.

In addition, according to the present invention, since a light-emitting portion, a bonding layer, and an ohmic contact electrode are all transparent to transmit visible light, there is an effect of no arrangement error issue in an exposure process.

Meanwhile, the effects of the present invention are not limited to the above-described effects, and various effects may be included within the range apparent to those skilled in the art from contents to be described below.

### DESCRIPTION OF DRAWINGS

FIG. 1 illustrates a structure of a conventional microdisplay panel.

FIG. 2 illustrates a conventional light-emitting diode-on-silicon (LEDoS) development approach.

FIG. 3 illustrates a conventional approach using an engineering monolithic epitaxy wafer.

FIG. 4 is an overall view illustrating a vertically-laminated microdisplay panel that does not require a color filter according to one embodiment of the present invention.

FIG. 5 illustrates that only light of a specific color is emitted from each of a plurality of light-emitting diode (LED) stacks of the vertically-laminated microdisplay panel that does not require a color filter according to one embodiment of the present invention.

FIG. 6 is a flowchart of a method of manufacturing a vertically-laminated microdisplay panel that does not require a color filter according to one embodiment of the present invention.

FIGS. 7 and 8 illustrate a process of manufacturing a plurality of front wafers in an n-side up form in the method of manufacturing a vertically-laminated microdisplay panel that does not require a color filter according to one embodiment of the present invention.

FIGS. 9 and 10 illustrate a process of manufacturing a plurality of front wafers in a p-side up form in the method of manufacturing a vertically-laminated microdisplay panel that does not require a color filter according to one embodiment of the present invention.

FIGS. 11 to 14 illustrate a process of manufacturing a vertically-laminated microdisplay panel according to the method of manufacturing a vertically-laminated microdisplay panel without a need for a color filter according to one embodiment of the present invention.

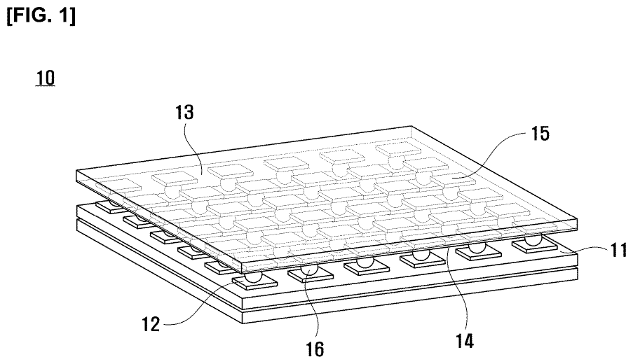

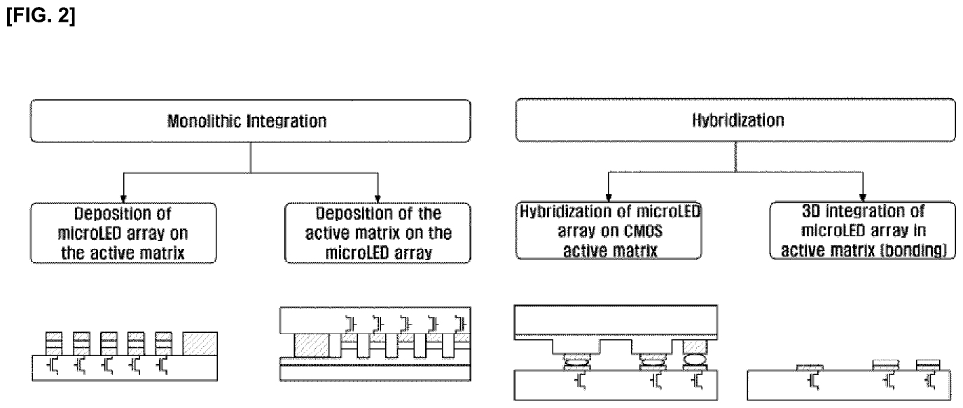

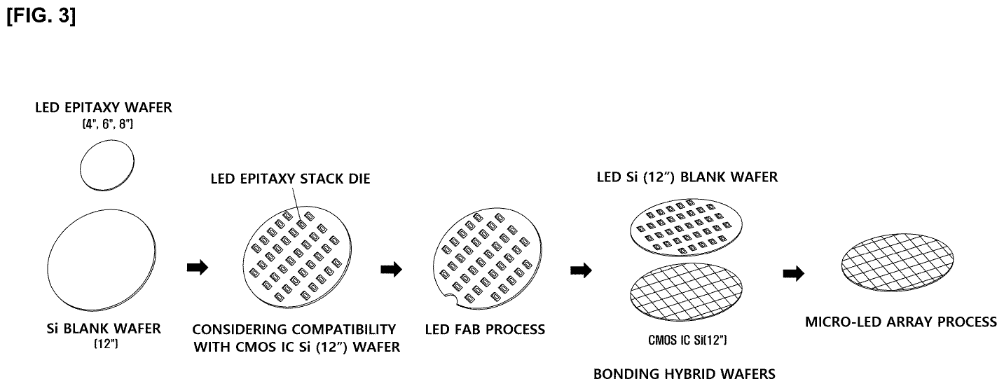

### MODES OF THE INVENTION

Hereinafter, some embodiments of the present invention will be described in detail with the accompanying exemplary drawings. When assigning reference numerals to components of each drawing, although the same components are illustrated in different drawings, the same components are given the same reference numerals as much as possible.

Further, in describing the present invention, a detailed description of related known configurations and functions will be omitted when it is determined that it may obscure the understanding of the embodiments of the present invention.

In addition, in describing components of the embodiment of the present invention, terms such as first, second, A, B, (a), and (b) may be used. These terms are used to distinguish one component from another component. However, the nature, the order, the sequence, or the number of components is not limited by these terms.

Hereinafter, a method S100 of manufacturing a vertically-laminated microdisplay panel that does not require a color filter according to one embodiment of the present invention will be described in detail with reference to the accompanying drawings.

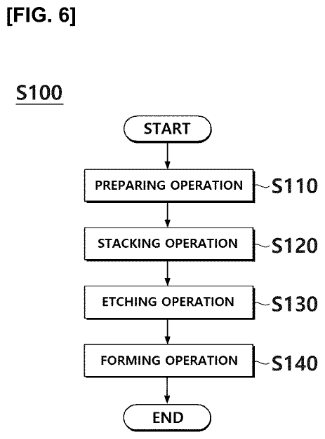

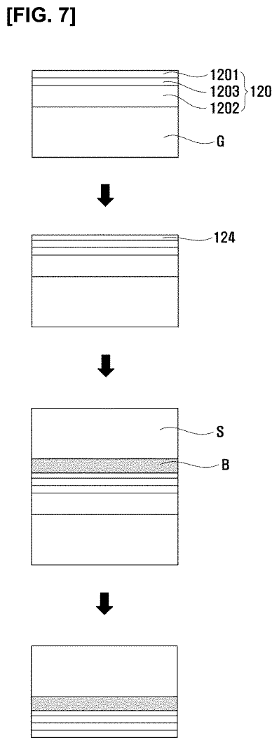

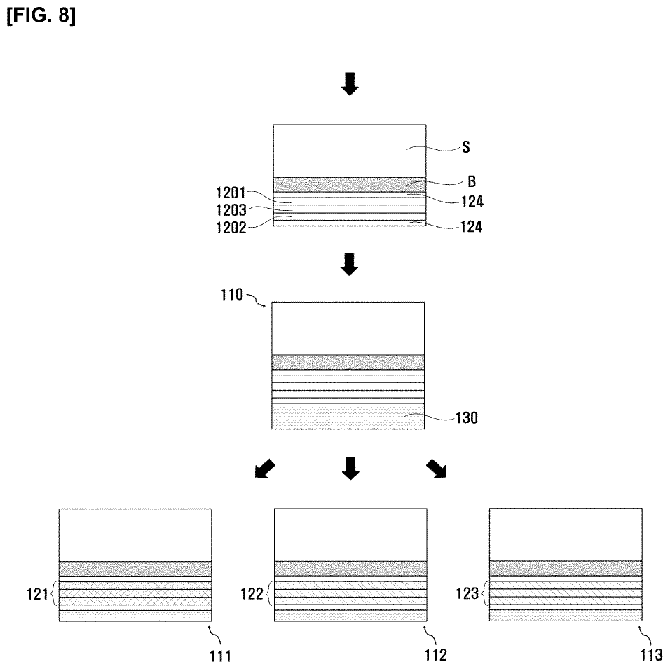

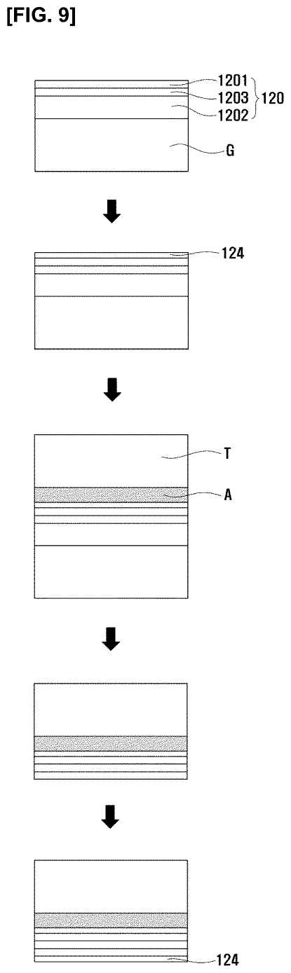

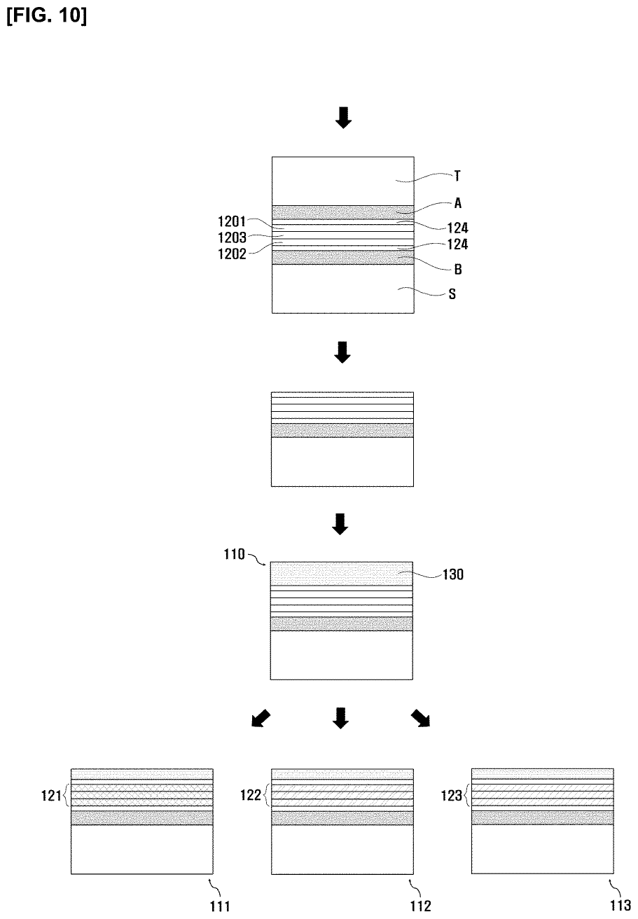

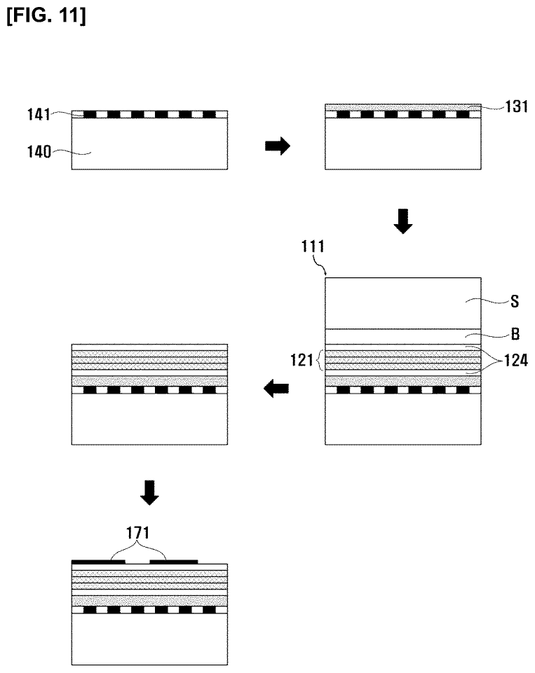

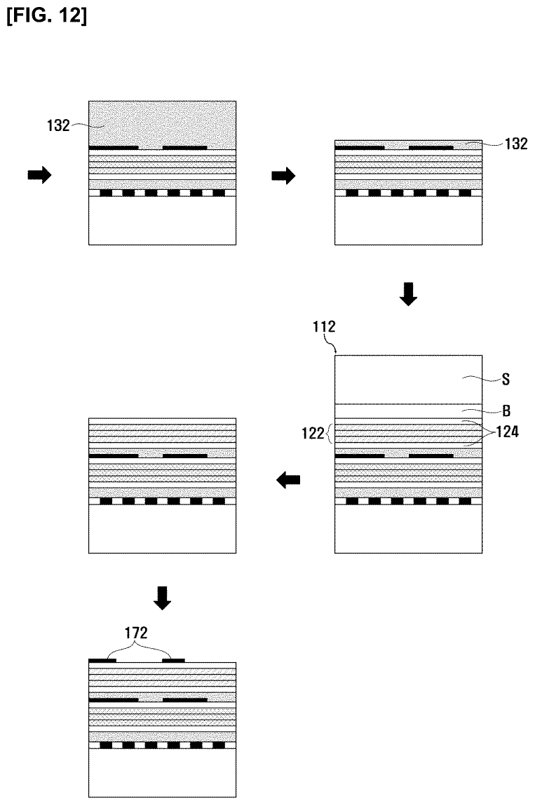

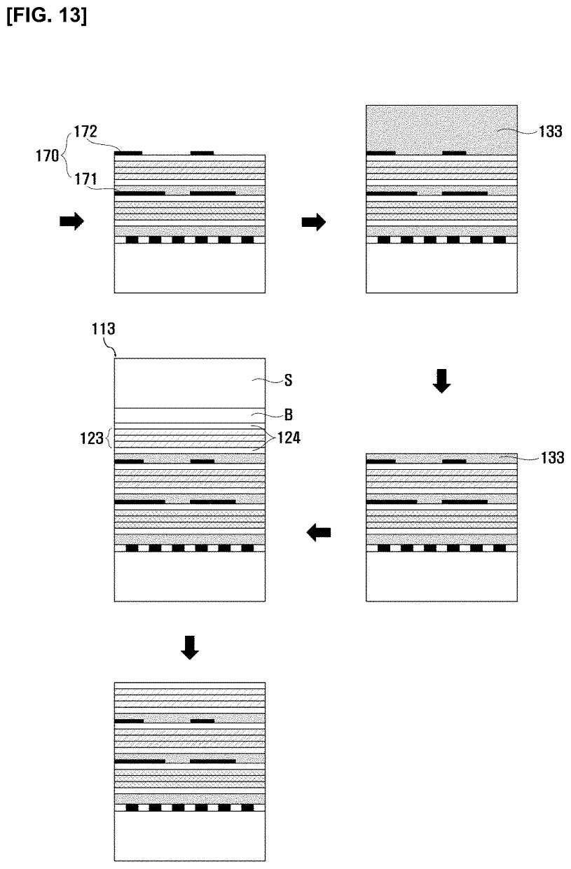

FIG. 6 is a flowchart of the method S100 of manufacturing a vertically-laminated microdisplay panel that does not require a color filter according to one embodiment of the present invention. FIGS. 7 and 8 illustrate a process of manufacturing a plurality of front wafers 110 in an n-side up form in the method S100 of manufacturing a vertically-laminated microdisplay panel that does not require a color filter according to one embodiment of the present invention. FIGS. 9 and 10 illustrate a process of manufacturing the plurality of front wafers in a p-side up form in the method S100 of manufacturing a vertically-laminated microdisplay panel that does not require a color filter according to one embodiment of the present invention. FIGS. 11 to 14 illustrate a process of manufacturing a vertically-laminated microdisplay panel according to the method S100 of manufacturing a vertically-laminated microdisplay panel that does not require a color filter according to one embodiment of the present invention.

As shown in FIGS. 6 to 14, the method S100 of manufacturing a vertically-laminated microdisplay panel that does not require a color filter according to one embodiment of the present invention includes a preparing operation S110, a stacking operation S120, an etching operation S130, and a forming operation S140.

The preparing operation S110 is an operation of preparing a plurality of front wafers 110 and preparing a back wafer 140.

The plurality of front wafers 110 may emit light having different colors, and the plurality of front wafers 110 may include a first front wafer 111 that emits light having a first color, a second front wafer 112 that emits light having a second color different from the first color, and a third front wafer 113 that emits light having a third color different from the first and second colors. Meanwhile, the first color, the second color, and the third color may be, for example, a red color, a green color, and a blue color, respectively, but are not limited thereto, and may include various other colors.

Here, the plurality of front wafers 110 include, more specifically, the first front wafer 111 including a support wafer S and a first light-emitting portion 121 disposed on the support wafer S, the second front wafer 112 including the support wafer S and a second light-emitting portion 122 disposed on the support wafer S, and the third front wafer 113 including the support wafer S and a third light-emitting portion 123 disposed on the support wafer S.

The support wafer S supports a light-emitting portion 120 (including the first light-emitting portion 121, the second light-emitting portion 122, or the third light-emitting portion 123) disposed thereon. The support wafer S is provided as a Si wafer having a (111), (110), or (100) crystal plane to prevent quality issues due to a difference in thermal expansion coefficient from occurring when a front wafer 110 is bonded to the back wafer 140 to be described below.

The light-emitting portion 120 may generate light and emit blue light, green light, or red light. In the present invention, when the light-emitting portion 120 emits blue light or green light, binary, ternary, and quaternary compounds such as InN, InGaN, GaN, AlGaN, AlN, and AlGaInN, which are Group III (Al, Ga, and In) nitride semiconductors among Group III-V compound semiconductors, may be disposed at an appropriate position and order on an initial growth wafer G and epitaxially grown.

In particular, in order to emit blue light or green light, a high-quality Group III nitride semiconductor such as InGaN having a high In composition should be preferentially formed on a Group III nitride semiconductor consisting of GaN, AlGaN, AlN, or AlGaInN, but the present invention is not limited thereto.

In addition, in the present invention, when the light-emitting portion 120 emits red light, binary, ternary, and quaternary compounds such as InP, InGaP, GaP, AlInP, AlGaP, AlP, and AlGaInP, which are Group III (Al, Ga, and In) phosphide semiconductors among Group III-V compound semiconductors, may be disposed at an appropriate position and order on the initial growth wafer G and epitaxially grown. In addition, in recent years, in order to further improve the development of equipment and process technologies and the value of display panel products, when red light is emitted, rather than a Group III phosphide semiconductor, a high-quality Group III nitride semiconductor such as InGaN with a high In composition of 30% or more may be preferentially formed on a Group III nitride semiconductor consisting of GaN, AlGaN, AlN, and AlGaInN.

In particular, in order to emit red light, a high-quality Group III phosphide semiconductor having a high In composition such as InGaP should be preferentially formed on a Group III phosphide semiconductor consisting of GaP, AlInP, AlGaP, AlP, AlGaInP, but the present invention is not limited thereto. Hereinafter, for convenience of description, a Group III nitride semiconductor will be mainly described.

Each light-emitting portion 120 may include, more specifically, a first semiconductor region 1201 (for example, a p-type semiconductor region), an active region 1203 (for example, a multi-quantum well (MQW)), and a second semiconductor region 1202 (for example, an n-type semiconductor region). The light-emitting portion 120 may have a structure in which the second semiconductor region 1202, the active region 1203, and the first semiconductor region 1201 are sequentially and epitaxially grown on the growth substrate G and may typically have an overall thickness of about 5.0 μm to about 8.0 μm by ultimately including a plurality of layers of Group III nitrides, but the present invention is not limited thereto.

Each of the first semiconductor region 1201, the active region 1203, and the second semiconductor region 1202 may be provided as a single layer or multiple layers, and although not shown, before the light-emitting portion 120 is epitaxially grown on the growth wafer G, necessary layers such as a buffer layer may be added to improve the quality of the epitaxially grown light-emitting portion 120. For example, the buffer layer may typically have a thickness of about 4.0 μm by including a compliant layer (CL) consisting of a nucleation layer (NL) and an un-doped semiconductor region to relieve stress and improve thin film quality. In addition, when the growth wafer G is removed using a laser lift-off (LLO) technique, a sacrificial layer may be provided between the NL and the un-doped semiconductor region, and a seed layer (SL) may also serve as the sacrificial layer.

The second semiconductor region 1202 has second conductivity (n-type) and is formed on the growth wafer G. This second semiconductor region 1202 may have a thickness of 2.0 μm to 3.5 μm.

The active region 1203 generates light using the recombination of electrons and holes and is formed on the second semiconductor region 1202. The active region 1203 may be provided as a plurality of layers to have a thickness of several tens nm.

The first semiconductor region 1201 has first conductivity (p-type) and is formed on the active region 1203. The first semiconductor region 1201 may be provided as a plurality of layers to have a thickness of several tens of nm to several μm, and an upper surface thereof may have gallium polarity (Ga-polarity).

That is, the active region 1203 is interposed between the first semiconductor region 1201 and the second semiconductor region 1202 so that holes of the first semiconductor region 1201, which is a p-type semiconductor region, recombine with electrons of the second semiconductor region 12012, which is an n-type semiconductor region, in the active region 1203 to generate light.

In addition, before the front wafer 110 and the back wafer 140 are bonded through a bonding layer 130, an ohmic contact electrode 124, which is optically transparent and electrically conductive and is in ohmic contact with and electrically connected to the light-emitting portion 120, may be formed on at least one of an upper surface and a lower surface of the light-emitting portion 120, which will be described below.

Meanwhile, the front wafer 110 of the present invention may be manufactured in an n-side up form in which the second semiconductor region 1202 having the second conductivity (n type) is exposed to the outside or in a p-side up form in which the first semiconductor region 1201 having the first conductivity (p type) is exposed to the outside.

As shown in FIGS. 7 and 8, a case in which the front wafer 110 of the present invention is manufactured in the n-side up form in which the second semiconductor region 1202 having the second conductivity (n type) is exposed to the outside is a case in which the growth wafer G is removed by performing bonding once, and a process is as follows.

First, when the light-emitting portion 120 emits blue light or green light, the second semiconductor region 1202, the active region 1203, and the first semiconductor region 1201 are sequentially stacked on a sapphire (α-phase Al2O3) growth wafer G, which is a wafer that is optically transparent to (theoretically) transmit 100% of a laser beam (single wavelength light) without absorbing the laser beam and has high temperature resistance, to epitaxially grow the light-emitting portion 120, an ohmic contact electrode 124, which is transparent and conductive, is formed on an upper surface of the first semiconductor region 1201, and then a silicon (Si) support wafer S having a (111), (110), or (100) crystal plane is bonded to the ohmic contact electrode 124 through a bonding layer B. Thereafter, the growth wafer G is separated from the light-emitting portion 120 using an LLO technique, the second semiconductor region 1202 is etched to reduce a thickness of the second semiconductor region 1202, an ohmic contact electrode 124, which is transparent and conductive, is formed on a lower surface of the second semiconductor region 1202 with the reduced thickness, and then a bonding layer 130 is deposited and formed on the lower ohmic contact electrode 124, thereby preparing the front wafer 110 with an n-side up form.

On the other hand, the light-emitting portion 120 that emits blue or green light may be formed on silicon (Si) growth wafer G having a (111) crystal plane instead of the sapphire (α-phase Al2O3) growth wafer G, and in this case, the silicon (Si) growth wafer G may be separated and removed through mechanical polishing or a chemical etching technique (chemical lift-off (CLO)).

In addition, when the light-emitting portion 120 emits red light, the second semiconductor region 1202, the active region 1203, and the first semiconductor region 1201 are sequentially stacked on a GaAs growth wafer G to epitaxially grow the light-emitting portion 120, an ohmic contact electrode 124, which is transparent and conductive, is formed on the upper surface of the first semiconductor region 1201, and then the silicon (Si) support wafer S having a (111), (110), or (100) crystal plane is bonded to the ohmic contact electrode 124 through a bonding layer B. Thereafter, the growth wafer G is separated from the light-emitting portion 120 using a CLO technique, the second semiconductor region 1202 is etched to reduce a thickness of the second semiconductor region 1202, an ohmic contact electrode 124, which is transparent and conductive, is formed on the lower surface of the second semiconductor region 1202 with the reduced thickness, and then a bonding layer 130 is deposited and formed on the lower ohmic contact electrode 124, thereby preparing the front wafer 110 with an n-side up form.

Accordingly, when the front wafer 110 has the n-side up form, the front wafer 110 has a structure in which the silicon (Si) support wafer S having a (111), (110), or (100) crystal plane, the bonding layer B, the ohmic contact electrode 124, the first semiconductor region 1201, the active region 1203, the second semiconductor region 1202, the ohmic contact electrode 124, and the bonding layer 130 are sequentially stacked. The silicon (Si) support wafer S has no difference in thermal expansion coefficient when the front wafer 110 is bonded to the silicon (Si) back wafer 140 later, thereby contributing to stabilizing the quality of a vertically-laminated microdisplay panel.

In addition, as shown in FIGS. 9 and 10, a case in which the front wafer 110 of the present invention is manufactured in the p-side up form in which the first semiconductor region 1201 having the first conductivity (p type) is exposed to the outside is a case in which the growth wafer G and a temporary wafer T are removed by performing bonding twice, and a process is as follows.

First, when the light-emitting portion 120 emits blue light or green light, the second semiconductor region 1202, the active region 1203, and the first semiconductor region 1201 are sequentially stacked on a sapphire (α-phase Al2O3) growth wafer G, which is a wafer that is optically transparent to (theoretically) transmit 100% of a laser beam (single wavelength light) without absorbing the laser beam and has high temperature resistance, to epitaxially grow the light-emitting portion 120, an ohmic contact electrode 124, which is transparent and conductive, is formed on the upper surface of the first semiconductor region 1201, and then the sapphire temporary wafer T, which a wafer that is optically transparent and has high temperature resistance, is bonded to the ohmic contact electrode through an adhesive layer A. Thereafter, the growth wafer G is separated from the light-emitting portion 120 using an LLO technique, the second semiconductor region 1202 is etched to reduce a thickness of the second semiconductor region 1202, an ohmic contact electrode 124, which is transparent and conductive, is formed on the lower surface of the second semiconductor region 1202 with the reduced thickness, and then the silicon (Si) support wafer S having a (111), (110), or (100) crystal plane is bonded to the ohmic contact electrode 124 through a bonding layer B. Thereafter, the temporary wafer T is separated from the adhesive layer A using an LLO technique, the adhesive layer A is etched and removed, and a bonding layer 130 is deposited and formed on the upper ohmic contact electrode 124, thereby preparing the front wafer 110 with a p-side up form. In addition, when Si having a (111), (110) or (100) crystal plane is used as the temporary wafer T instead of sapphire, the temporary wafer T is separated and removed through a CLO process instead of an LLO process.

On the other hand, the light-emitting portion 120 that emits blue or green light may be formed on silicon (Si) growth wafer G having a (111) crystal plane instead of the sapphire (α-phase Al2O3) growth wafer G, and in this case, the Si growth wafer G and the support wafer S are separated and removed through mechanical polishing or a CLO technique.

In addition, when the light-emitting portion 120 emits red light, the second semiconductor region 1202, the active region 1203, and the first semiconductor region 1201 are sequentially stacked on a GaAs growth wafer G to epitaxially grow the light-emitting portion 120, an ohmic contact electrode 124, which is transparent and conductive, is formed on the upper surface of the first semiconductor region 1201, and then the sapphire support wafer S, which a wafer that is an optically transparent and has high temperature resistance, is bonded to the ohmic contact electrode 124 through a bonding layer B. Thereafter, the growth wafer G is separated from the light-emitting portion 120 using a CLO technique, the second semiconductor region 1202 is etched to reduce a thickness of the second semiconductor region 1202, an ohmic contact electrode 124, which is transparent and conductive, is formed on the lower surface of the second semiconductor region 1202 with the reduced thickness, and then the silicon (Si) support wafer S having a (111), (110), or (100) crystal plane is bonded to the ohmic contact electrode 124 through a bonding layer B. Thereafter, the temporary wafer T is separated from the adhesive layer A using an LLO technique, the adhesive layer A is etched and removed, and a bonding layer 130 is deposited and formed on the upper ohmic contact electrode 124, thereby preparing the front wafer 110 with a p-side up form. In addition, when Si having a (111), (110) or (100) crystal plane is used as the temporary wafer T instead of sapphire, the temporary wafer T is separated and removed through a CLO process instead of an LLO process.

Accordingly, when the front wafer 110 has the p-side up form, the front wafer 110 has a structure in which the silicon (Si) support wafer S having a (111), (110), or (100) crystal plane, the bonding layer B, the ohmic contact electrode 124, the second semiconductor region 1202, the active region 1203, the first semiconductor region 1201, the ohmic contact electrode 124, and the bonding layer 130 are sequentially stacked. The silicon (Si) support wafer S has no difference in thermal expansion coefficient when the front wafer 110 is bonded to the silicon (Si) back wafer 140 later, thereby contributing to stabilizing the quality of a vertically-laminated microdisplay panel.

Furthermore, in a process of manufacturing the front wafer 110 with the p-side up or n-side up form described above, before the ohmic contact electrode 124 is formed on a surface of the first semiconductor region 1201 or a surface of the second semiconductor region 1202, when the surface of the first semiconductor region 1201 is exposed (p-side up form) or the surface of the second semiconductor region 1202 is exposed (n-side up form), each surface may be polished and smoothly planarized through mechanical polishing (MP) or chemical-mechanical polishing (CMP) to have a smooth surface.

Meanwhile, the ohmic contact electrode 124 of the front wafer 110 is formed of a material having transparency and conductivity. When the ohmic contact electrode 124 is formed in contact with the first semiconductor region 1201 which is a p-type semiconductor, a material of the ohmic contact electrode 124 may include NiO, PtO, PdO, AgO2, Au, Rh2O3, RuO2, In2O3, SnO2, zinc oxide (ZnO), indium zinc oxide (IZO), indium tin oxide (ITO), and indium germanium zinc oxide (IGZO). When the ohmic contact electrode 124 is formed in contact with the second semiconductor region 1202 which is an n-type semiconductor, the material of the ohmic contact electrode 124 may include TiN, CrN, VN, In2O3, SnO2, ZnO, IZO, ITO, and IGZO. Furthermore, since the surface of the second semiconductor region 1202 having nitrogen polarity (N-polarity) has a much higher surface roughness than the surface of the first semiconductor region 1201 having gallium polarity (Ga-polarity), it is preferable to introduce a CMP process of polishing and planarizing the surface of the second semiconductor region 1202 before forming the ohmic contact electrode 124 which is transparent and conductive.

In addition, a surface of the ohmic contact electrode 124 formed on the front wafer 110 may also be polished and smoothly planarized through MP or CMP.

The back wafer 140 is a CMOS wafer in which, as an active driving IC driven through an active matrix (AM) method, a plurality of CMOS electrode pads 141 are arrayed on an upper surface thereof. A passivation layer may be formed between the plurality of CMOS electrode pads 141.

Here, the back wafer 140 is provided as a Si wafer having a (100) crystal plane and is preferably provided as an 8-inch or 12-inch Si wafer according to a standard CMOS IC process.

The stacking operation S120 is an operation of vertically stacking a plurality of light-emitting portions 212 and a plurality of bonding layers 230 on the back wafer 140 by repeating a process of bonding an inverted front wafer 110 onto the back wafer 140 through the bonding layer 130 such that the light-emitting portion 120 of the front wafer 110 faces the CMOS electrode pad 141 of the back wafer 140, that is, the light-emitting portion 120 of the front wafer 110 and the CMOS electrode pad 141 of the back wafer 140 face each other, and then removing the support wafer S.

Here, since the support wafer S of the front wafer 110 is a Si wafer having a (111), (110), or (100) crystal plane, and the back wafer 140 is also a Si wafer having a (100) crystal plane, there is no difference in thermal expansion coefficient during bonding, thereby contributing to stabilizing the quality of a vertically-laminated microdisplay panel.

In this case, the stacking operation S120 uses properties in which smooth surfaces adhere to each other due to van der Waals forces without using a high voltage or an external electric field. Accordingly, it is preferable that, before the front wafer 110 and the back wafer 140 are bonded through the bonding layer 130, a CMP process is introduced so that the roughness of each bonding surface is very low (Rq<0.5 nm @ 2 μm×2 μm) and there are no particles such as impurities between surfaces. To this end, in the stacking operation S120, before the front wafer 110 is bonded to the back wafer 140, surfaces of the bonding layer 130 of the front wafer 110 and the bonding layer 230 of the back wafer 140 may each be polished and smoothly planarized through MP or CMP.

Here, the bonding layer 130 (including a first bonding layer 131, a second bonding layer 132, and a third bonding layer 133 described below) is formed of a ceramic material that is optically transparent and electrically conductive, that is, transparent and conductive. Here, the term “optically transparent” means being transparent (transmittance of 80% or more) or translucent (transmittance of 50% or more) in a wavelength band of light (including visible light) used in an optical exposure (photolithography) process, and the term “electrically conductive” means having an electrical resistance of less than 10-3 Ω/cm. The ceramic material with such transparency and conductivity includes a transparent conductive oxide (TCO), a transparent conductive nitride (TCN), and a (transparent conductive oxide nitride (TCON).

In this case, when the ceramic material is a TCO, the ceramic material may include In2O3, SnO2, ZnO, IZO, ITO, and IGZO, when the ceramic material is a TCN, the ceramic material may include TiN, CrN, and VN, and when the ceramic material is a TCON, the ceramic material may include InON, SnON, ZnON, IZON, ITON, and IGZON.

As shown in FIGS. 11 to 13, the stacking operation S120 includes, in more detail, a first stacking operation, a second stacking operation, and a third stacking operation.

The first stacking operation is an operation of bonding the first front wafer 111 onto the back wafer 140 through the first bonding layer 131 such that the first light-emitting portion 121 of the first front wafer 111 with an n-side up (or p-side up) form faces the CMOS electrode pad 141 of the back wafer 140, removing the support wafer S using MP, a CLO technique, and the like, and then etching and removing the bonding layer B to stack the first light-emitting portion 121 on the back wafer 140.

In this case, in the first stacking operation, after the support wafer S and bonding layer B are removed, a first metal layer 171 may be formed on a portion of the first light-emitting portion 121, that is, at portions in which a second LED stack 220 and a third LED stack 230 are to be formed.

The second stacking operation is an operation of bonding the second front wafer 112 onto the back wafer 140, to which the first light-emitting portion 121 having ohmic contact electrodes 124 formed on upper and lower surfaces thereof is bonded, through the second bonding layer 132 such that the second light-emitting portion 122 of the second front wafer 112 with an n-side up (or p-side up) form faces the CMOS electrode pad 141 of the back wafer 140, removing the support wafer S using MP and a CLO technique, and then etching and removing the bonding layer B to stack the second light-emitting portion 122 on the first light-emitting portion 121.

In this case, in the second stacking operation, after the support wafer S and bonding layer B are removed, a second metal layer 172 may be formed on a portion of the second light-emitting portion 122, that is, at a portion in which the third LED stack 230 is to be formed.

Meanwhile, each of the first metal layer 171 and the second metal layer 172 described above may be composed of a single layer or multiple layers. When each of the first metal layer 171 and the second metal layer 172 composed of multiple layers, a lower layer may have an absorptive property to block light generated from below, and an upper layer may have a reflective property to reflect light generated from above. For example, Ag/Ni may correspond to the multiple layers. In addition, each of the first metal layer 171 and the second metal layer 172 may include an adhesive layer formed of Ti, Cr, Ni, or the like to improve adhesiveness. In addition, considering reflection/absorption, a thickness of each of the first metal layer 171 and the second metal layer 172 is preferably the minimum thickness to block 100% of light therebelow. This is because when the thickness is thick, there is a difficulty in a transparent conductive bonding and planarizing process.

The third stacking operation is an operation of bonding the third front wafer 113 onto the back wafer 140, to which the second light-emitting portion 122 having ohmic contact electrodes 124 formed on upper and lower surfaces thereof is bonded, through the third bonding layer 133 such that the third light-emitting portion 123 of the third front wafer 113 with an n-side up (or p-side up) form faces the CMOS electrode pad 141 of the back wafer 140, removing the support wafer S using MP and a CLO technique, and then etching and removing the bonding layer B to stack the third light-emitting portion 123 on the second light-emitting portion 122.

Thus, a structure in which the back wafer, the first bonding layer 131, the first light-emitting portion 121 having ohmic contact electrodes 124 formed on upper and lower surfaces thereof, the second bonding layer 132, the second light-emitting portion 122 having ohmic contact electrodes 124 formed on upper and lower surfaces thereof, the third bonding layer 133, and the third light-emitting portion 123 having ohmic contact electrodes 124 formed on upper and lower surfaces thereof are vertically stacked, and the first metal layer 171 and the second metal layer 172 are formed on portions of the first light-emitting portion 121 and the second light-emitting portion 122, respectively, is obtained.

That is, in the present invention, considering a wavelength of light, it is preferable that first color light of the first light-emitting portion 121 of a lower layer is red light with a long wavelength, second color light of the second light-emitting portion 122 of an intermediate layer is green light, and third color light of the third light-emitting portion 123 of an upper layer is blue light with a short wavelength, but the present invention is not limited thereto.

Afterward, in the stacking operation S120, after the front wafer 110 is bonded to the back wafer 140, it is necessary perform heat treatment on the bonding layer 130 at a temperature of less than 400° C. such that a CMOS circuit of the back wafer 140 is not damaged.

The etching operation S130 is an operation of etching and dividing the plurality of stacked light-emitting portions 120 and bonding layers 130 into preset units to place and arrange the plurality of LED stacks 200 on the plurality of CMOS electrode pads 141 and an operation that eliminates the need for a conventional process of arranging the LED stacks of the front wafer 110 and the CMOS electrode pads 141 of the back wafer 140.

That is, in the etching operation S130, the light-emitting portion 120, the bonding layer 130, and the ohmic contact electrode 124 are vertically etched until a surface of the back wafer 140 or an area adjacent thereto is exposed to arrange the plurality of LED stacks 200 on the arrayed, that is, arranged, CMOS electrode pads 141. Here, the preset unit may refer to a pixel or subpixel unit and may refer to a diameter (width) of the plurality of LED stacks 200.

In this case, the light-emitting portion 120, the bonding layer 130, and the ohmic contact electrode 124 of the present invention are all transparent to transmit visible light, and thus there is an advantage in that there is no arrangement error issue in an exposure process. In addition, since a ceramic material is used rather than a metal, both the bonding layer 130 and the ohmic contact electrode 124 of the present invention are easy to etch in a plasma dry process, and there is an advantage in that a problem of re-deposition of etch by-products does not occur.

Meanwhile, the plurality of LED stacks 200 include a first LED stack 210 for emitting only light having a first color, the second LED stack 220 for emitting only light having a second color, and the third LED stack 230 for emitting only light having a third color.

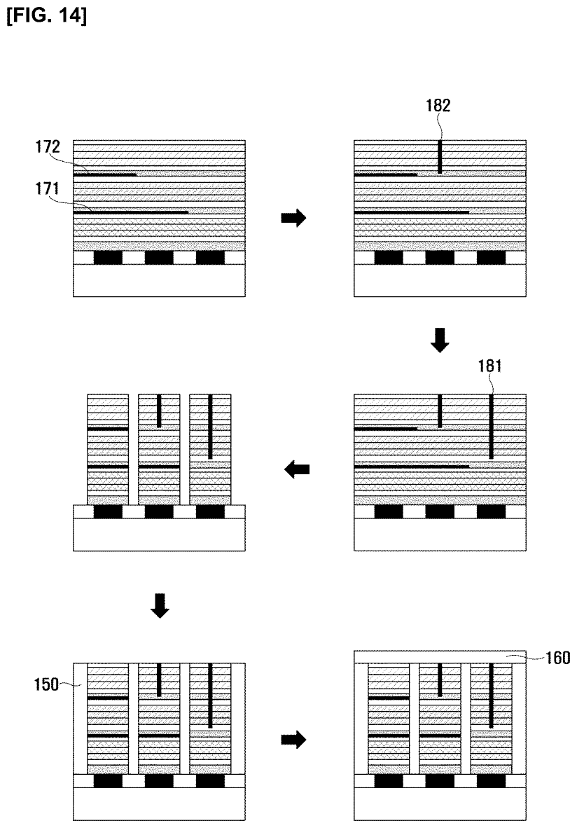

Meanwhile, as shown in FIG. 14, in the etching operation S130, a through-hole may be formed through etching to pass through the third light-emitting portion 123 and the second light-emitting portion 122 at a portion in which the first LED stack 210 is formed, and then a first short path 181 may be formed in the through-hole. In this case, an upper side of the first short path 181 may be in contact with and electrically connected to the common electrode 160, and a lower side thereof may be electrically connected to the ohmic contact electrode 124 or the third bonding layer 133 below the third light-emitting portion 123.

In addition, the etching operation S130, a through-hole may be formed to pass through the third light-emitting portion 123 at a portion in which the second LED stack 220 is formed, and then a second short path 182 may be formed in the through-hole. In this case, an upper side of the second short path 182 may be in contact with and electrically connected to the common electrode 160, and a lower side thereof may be electrically connected to the ohmic contact electrode 124 or the second bonding layer 132 below the second light-emitting portion 122.

Here, after a through-hole is formed, a short path 180 may be formed by filling the through-hole through a direct self-align method or by filling the through-hole through a liquid coating method such as solgel, but the present invention is not limited thereto. Any method may be used as long as the method is a method of forming the short path 180 in the through-hole.

Meanwhile, a process of arranging the plurality of LED stacks 200 and a process of forming the short path 180 in the etching operation S130 are not limited to this order.

The first short path 181 and the second short path 182 described above may be formed of a metallic material or an optically transparent and electrically conductive material. When the first short path 181 and the second short path 182 are formed of a metallic material, the first short path 181 and the second short path 182 may include Ag, Cu, Au, Pd, Pt, Ni, Mo, W, electrically conductive nanoparticles, etc., but the present invention is not limited thereto. In addition, when the first short path 181 and the second short path 182 are formed of an optically transparent and electrically conductive material, it is preferable that the first short path 181 and the second short path 182 are formed of a material having low resistance and high transmittance characteristics. The material may include In2O3, SnO2, ZnO, IZO, ITO, IGZO, etc., but the present invention is not limited thereto.

After the etching operation S130, the first LED stack 210 may emit only light having a first color by forming the first short path 181 to pass through the third light-emitting portion 123 and the second light-emitting portion 122 so that a current does not flow into and bypasses the third light-emitting portion 123 and the second light-emitting portion 122.

In addition, the second LED stack 220 may emit only light having a second color by forming the second short path 182 to pass through the third light-emitting portion 123 so that a current does not flow into and bypasses the third light-emitting portion 123, and blocking light generated from the first light-emitting portion 121 through the first metal layer 171 formed on the first light-emitting portion 121.

In addition, the third LED stack 230 may emit only light having a third color by blocking light generated from the second light-emitting portion 122 and the first light-emitting portion 121 through the second metal layer 172 formed on the second light-emitting portion 122 and the first metal layer 171 formed on the first light-emitting portion 121.

That is, each of the plurality of LED stacks 200 emits only light of a specific color by blocking light generated from at least one of the plurality of light-emitting portions 120 through the above-described metal layer 170 or short path 180 or blocking current flow into at least one of the plurality of light-emitting portions 120.

Meanwhile, in the present invention, the light-emitting areas of the plurality of LED stacks 200 may all be the same, and an operating voltage may be set differently for each of the plurality of LED stacks 200. Specifically, in the first LED stack 210, the third light-emitting portion 123 and the second light-emitting portion 122 may both become conductive through the first short path 181 so that a voltage (for example, 3 V) may be applied to only the first light-emitting portion 121, in the second LED stack 220, only the third light-emitting portion 123 may become conductive through the second short path 182 so that a voltage (for example, 6 V) may be applied to the second light-emitting portion 122 and the first light-emitting portion 121, which are connected in series, and in the third LED stack 230, a voltage (for example, 9 V) may be applied to the first to third light-emitting portions 121 to 123, which are connected in series.

The forming operation S140 is an operation of forming a mold portion 150 that fills a space between the plurality of arranged LED stacks 200, and then forming the common electrode 160 on the plurality of LED stacks 200.

More specifically, in the forming operation S140, after the mold portion 150 is formed to fill the space between the plurality of arranged LED stacks 200 and support the LED stacks 200 and the mold portion 150 is etched such that upper portions of the plurality of LED stacks 200 are exposed, the common electrode 160 is formed on the exposed upper portions of the plurality of LED stacks 200, thereby completing a vertically stacked LEDOS structure. Here, similar to the ohmic contact electrode 124, the common electrode 160 may be formed of a material that is transparent and conductive. When the common electrode 160 is an anode, a material of the common electrode 160 may include NiO, PtO, PdO, AgO2, Au, Rh2O3, RuO2, In2O3, SnO2, ZnO, IZO, ITO, and IGZO, and when the common electrode 160 is a cathode, the material of the common electrode 160 may include TiN, CrN, VN, In2O3, SnO2, ZnO, IZO, ITO, and IGZO.

In addition, a surface of the common electrode 160 may also be polished and smoothly planarized through MP or CMP.

Furthermore, although not shown, a protection layer may be additionally formed using a transparent organic material to protect the common electrode 160 from the atmospheric environment.

Hereinafter, a vertically-laminated microdisplay panel 100 that does not require a color filter according to one embodiment of the present invention will be described in detail with reference to the accompanying drawings.

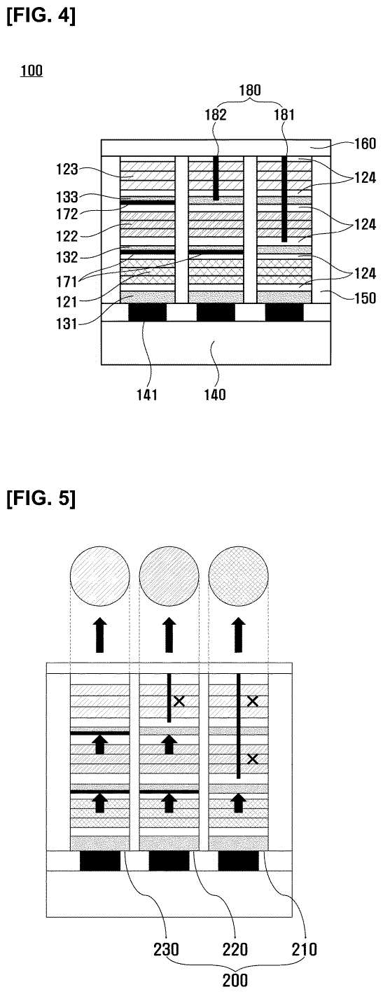

FIG. 4 is an overall view of the vertically-laminated microdisplay panel 100 that does not require a color filter according to one embodiment of the present invention. FIG. 5 illustrates that only light of a specific color is emitted from each of a plurality of LED stacks 200 of the vertically-laminated microdisplay panel 100 that does not require a color filter according to one embodiment of the present invention.

As shown in FIGS. 4 and 5, the vertically-laminated microdisplay panel 100 that does not require a color filter according to one embodiment of the present invention includes a back wafer 140, the plurality of LED stacks 200, a mold portion 150, and a common electrode 160.

The back wafer 140 is a CMOS wafer in which, as an active driving IC driven through an AM method, a plurality of CMOS electrode pads 141 are arrayed on an upper surface thereof. A passivation layer may be formed between the plurality of CMOS electrode pads 141.

Here, the back wafer 140 is provided as a Si wafer having a (100) crystal plane and is preferably provided as an 8-inch or 12-inch Si wafer according to a standard CMOS IC process.

The plurality of LED stacks 200 are formed by vertically stacking a plurality of light-emitting portions 120 and a plurality of bonding layers 130 on the back wafer 140 and are arranged on the plurality of CMOS electrode pads 141.

The plurality of LED stacks 200 include a first LED stack 210 for emitting only light having a first color, a second LED stack 220 for emitting only light having a second color, and a third LED stack 230 for emitting only light having a third color. Meanwhile, the first color, the second color, and the third color may be, for example, a red color, a green color, and a blue color, respectively, but are not limited thereto, and may include various other colors.

In addition, the first LED stack 210, the second LED stack 220, and the third LED stack 230 may each have a tandem structure in which the plurality of light-emitting portions 120 and the plurality of bonding layers 130 are vertically stacked, and more specifically, may include a first light-emitting portion 121 bonded onto the CMOS electrode pad 141 through a first bonding layer 131 to emit light having the first color, a second light-emitting portion 122 bonded onto the first light-emitting portion 121 through a second bonding layer 132 to emit light having the second color, and a third light-emitting portion 123 bonded onto the second light-emitting portion 122 through a third bonding layer 133 to emit light having the third color.

That is, in the present invention, considering a wavelength of light, it is preferable that first color light of the first light-emitting portion 121 of a lower layer is red light with a long wavelength, second color light of the second light-emitting portion 122 of an intermediate layer is green light, and third color light of the third light-emitting portion 123 of an upper layer is blue light with a short wavelength, but the present invention is not limited thereto.

In the present invention, each of the first light-emitting portion 121, the second light-emitting portion 122, and the third light-emitting portion 123 may be stacked in an n-side up form or a p-side up form, and an ohmic contact electrode 124 that is in ohmic contact with and electrically connected to the light-emitting portion 120 may be formed on at least one of an upper surface and a lower surface of each of the first light-emitting portion 121, the second light-emitting portion 122, and the third light-emitting portion 123.

The ohmic contact electrode 124 is formed of a material which is transparent and conductive. When the ohmic contact electrode 124 is formed in contact with a first semiconductor region 1201 which is a p-type semiconductor, a material of the ohmic contact electrode 124 may include NiO, PtO, PdO, AgO2, Au, Rh2O3, RuO2, In2O3, SnO2, ZnO, IZO, ITO, and IGZO. When the ohmic contact electrode 124 is formed in contact with the second semiconductor region 1202 which is an n-type semiconductor, a material of the ohmic contact electrode 124 may include TiN, CrN, VN, In2O3, SnO2, ZnO, IZO, ITO, and IGZO. Furthermore, since a surface of a second semiconductor region 1202 having nitrogen polarity (N-polarity) has a much higher surface roughness than a surface of the first semiconductor region 1201 having gallium polarity (Ga-polarity), it is preferable to introduce a CMP process of polishing and planarizing the surface of the second semiconductor region 1202 before forming the ohmic contact electrode 124 which is transparent and conductive.

In addition, a surface of the ohmic contact electrode 124 formed on the front wafer 110 may also be polished and smoothly planarized through MP or CMP.

Meanwhile, the following contents regarding the light-emitting portion 120 are the same as those of the method S100 of manufacturing a vertically-laminated microdisplay panel that does not require a color filter, and thus redundant descriptions thereof will be omitted.

In addition, the bonding layer 130 (including the first bonding layer 131, the second bonding layer 132, and the third bonding layer 133) is formed of a ceramic material that is optically transparent and electrically conductive, that is, transparent and conductive. Here, the term “optically transparent” means being transparent (transmittance of 80% or more) or translucent (transmittance of 50% or more) in a wavelength band of light (including visible light) used in an optical exposure (photolithography) process, and the term “electrically conductive” means having an electrical resistance of less than 10-3 Ω/cm. The ceramic material with such transparency and conductivity includes a TCO, a TCN, and a TCON.

In this case, when the ceramic material is a TCO, the ceramic material may include In2O3, SnO2, ZnO, IZO, ITO, and IGZO, when the ceramic material is a TCN, the ceramic material may include TiN, CrN, and VN, and when the ceramic material is a TCON, the ceramic material may include InON, SnON, ZnON, IZON, ITON, and IGZON.

In the present invention, each of the plurality of LED stacks 200 emits only light of a specific color without a color filter by blocking light generated from at least one of the plurality of light-emitting portions 120 or forming a short path 180 in at least one light-emitting portion 120 of the plurality of light-emitting portions 120 so that a current does not flow into and bypasses the light-emitting portion 120.

More specifically, among the plurality of LED stacks 200, the first LED stack 210 of the present invention may emit only light having a first color by forming a first short path 181 to pass through the third light-emitting portion 123 and the second light-emitting portion 122 so that a current does not flow into and bypasses the third light-emitting portion 123 and the second light-emitting portion 122. In this case, an upper side of the first short path 181 may be in contact with and electrically connected to the common electrode 160, and a lower side thereof may be electrically connected to the ohmic contact electrode 124 or the third bonding layer 133 below the third light-emitting portion 123.

In addition, the second LED stack 220 may emit only light having a second color by forming a second short path 182 to pass through the third light-emitting portion 123 so that a current does not flow into and bypasses the third light-emitting portion 123, and blocking light generated from the first light-emitting portion 121 through the first metal layer 171 formed on the first light-emitting portion 121. In this case, an upper side of the second short path 182 may be in contact with and electrically connected to the common electrode 160, and a lower side thereof may be electrically connected to the ohmic contact electrode 124 or the second bonding layer 132 below the second light-emitting portion 122.

In addition, the third LED stack 230 may emit only light having a third color by blocking light generated from the second light-emitting portion 122 and the first light-emitting portion 121 through the second metal layer 172 formed on the second light-emitting portion 122 and the first metal layer 171 formed on the first light-emitting portion 121.

Meanwhile, each of the first metal layer 171 and the second metal layer 172 may be provided as a single layer or multiple layers. When each of the first metal layer 171 and the second metal layer 172 is provided as multiple layers, a lower layer may have an absorptive property to block light generated from below, and an upper layer may have a reflective property to reflect light generated from above. For example, Ag/Ni may correspond to the multiple layers. In addition, each of the first metal layer 171 and the second metal layer 172 may include an adhesive layer formed of Ti, Cr, Ni, or the like to improve adhesiveness. In addition, considering reflection/absorption, each of the first metal layer 171 and the second metal layer 172 has preferably a minimum thickness to block 100% of light therebelow. This is because when the thickness is great, there is difficulty in a transparent conductive bonding and planarizing process.

In addition, the first short path 181 and the second short path 182 described above may be formed of a metallic material or an optically transparent and electrically conductive material. When the first short path 181 and the second short path 182 are formed of a metallic material, the first short path 181 and the second short path 182 may include Ag, Cu, Au, Pd, Pt, Ni, Mo, W, and electrically conductive nanoparticles, etc., but the present invention is not limited thereto. In addition, when the first short path 181 and the second short path 182 are formed of an optically transparent and electrically conductive material, it is preferable that the first short path 181 and the second short path 182 are formed of a material having low resistance and high transmittance characteristics. Such materials may include In2O3, SnO2, ZnO, IZO, ITO, IGZO, etc., but the present invention is not limited thereto.

Meanwhile, the plurality of LED stacks 200 disposed and arranged on the plurality of CMOS electrode pads 141 may be divided into preset units, and here, the preset units may be pixel or subpixel units and refer to a diameter (width) of the plurality of LED stacks 200.

In this case, in the present invention, the light-emitting areas of the plurality of LED stacks 200 may all be the same, and an operating voltage may be set differently for each of the plurality of LED stacks 200. Specifically, in the first LED stack 210, the third light-emitting portion 123 and the second light-emitting portion 122 may both become conductive through the first short path 181 so that a voltage (for example, 3 V) may be applied to only the first light-emitting portion 121, in the second LED stack 220, only the third light-emitting portion 123 may become conductive through the second short path 182 so that a voltage (for example, 6 V) may be applied to the second light-emitting portion 122 and the first light-emitting portion 121, which are connected in series, and in the third LED stack 230, a voltage (for example, 9 V) may be applied to the first to third light-emitting portions 121 to 123, which are all be connected in series.

The mold portion 150 supports a vertically stacked LEDOS structure and is disposed to fill a space between the plurality of arranged LED stacks 200.

The common electrode 160 is formed on the plurality of LED stacks 200 on which the mold portion 150 is formed. Similar to the ohmic contact electrode 124, the common electrode 160 may be formed of a material that is transparent and conductive. When the common electrode 160 is a positive electrode, a material of the common electrode 160 may include NiO, PtO, PdO, AgO2, Au, Rh2O3, RuO2, In2O3, SnO2, ZnO, IZO, ITO, or IGZO. When the common electrode 160 is a negative electrode, the material of the common electrode 160 may include TiN, CrN, VN, In2O3, SnO2, ZnO, IZO, ITO, or IGZO.

In addition, a surface of the common electrode 160 may also be polished and smoothly planarized through MP or CMP.

Furthermore, although not shown, a protection layer may be additionally formed using a transparent organic material to protect the common electrode 160 from the atmospheric environment.

As described above, although all the components constituting embodiments disclosed herein were described as being combined or combined to operate as one, the present invention is not necessarily limited to these embodiments. That is, one or more of all the components may be selectively combined to operate as one without departing from the scope of the purpose of the present invention.

In addition, the terms “include,” “consist,” or “have” as described above mean that a corresponding component may be intrinsic, unless specifically stated otherwise, and it should interpreted as including other components rather than excluding other components. All terms including technical or scientific terms have the same meanings as those commonly understood by those skilled in the art to which the present invention pertains, unless defined otherwise. Commonly used terms, such as terms defined in a dictionary, should be interpreted as being consistent with the contextual meaning of the related art and are not interpreted in an ideal or excessively formal meaning unless explicitly defined herein.

The above description is merely illustrative of the technical idea of the present invention, and those skilled in the art to which the present invention pertains may make various modifications and variations without departing from the essential characteristics of the present invention.

Accordingly, embodiments disclosed in the present invention are not intended to limit the technical idea of the present invention, but are for illustrative purposes, and the scope of the technical idea of the present invention is not limited by these embodiments. The spirit and scope of the present invention should be interpreted by the appended claims and encompass all equivalents falling within the scope of the appended claims.

1. A vertically-laminated microdisplay panel that does not require a color filter, comprising:
a back wafer having an upper surface on which a plurality of complementary metal oxide semiconductor (CMOS) electrode pads are arranged;
a plurality of light-emitting diode (LED) stacks of which a plurality of light-emitting portions and a plurality of bonding layers are vertically stacked on the back wafer and which are arranged on the plurality of CMOS electrode pads; and
a common electrode formed on the plurality of LED stacks,
wherein each of the plurality of LED stacks emits only light of a specific color by blocking light generated from at least one light-emitting portion of the plurality of light-emitting portions or forming a short path in at least one light-emitting portion of the plurality of light-emitting portions so that a current does not flow into and bypasses the light-emitting portion,
wherein the plurality of LED stacks include a first LED stack configured to emit only light having a first color, a second LED stack configured to emit only light having a second color, and a third LED stack configured to emit only light having a third color, and
each of the first LED stack, the second LED stack, and the third LED stack includes a first light-emitting portion bonded onto the CMOS electrode pad through a first bonding layer to emit light having the first color, a second light-emitting portion bonded onto the first light-emitting portion through a second bonding layer to emit light having the second color, and a third light-emitting portion bonded onto the second light-emitting portion through a third bonding layer to emit light having the third color,
wherein the first LED stack emits only the light having the first color by forming the short path to pass through the third light-emitting portion and the second light-emitting portion so that a current does not flow into and bypasses the third light-emitting portion and the second light-emitting portion,
the second LED stack emits only the light having the second color by forming the short path to pass through the third light-emitting portion so that a current does not flow into and bypasses the third light-emitting portion and blocking light generated from the first light-emitting portion, and
the third LED stack emits only the light having the third color by blocking light generated from the second light-emitting portion and the first light-emitting portion.

2-3. (canceled)

4. The vertically-laminated microdisplay panel of claim 1, wherein the second LED stack blocks the light generated from the first light-emitting portion through a metal layer formed on the first light-emitting portion, and
the third LED stack blocks the light generated from the second light-emitting portion and the first light-emitting portion through the metal layer formed on each of the second light-emitting portion and the first light-emitting portion.

5. The vertically-laminated microdisplay panel of claim 4, wherein the metal layer includes a lower layer which has an absorptive property to block light generated from below and an upper layer which has a reflective property to reflect light generated from above.

6. The vertically-laminated microdisplay panel of claim 1, wherein the short path is formed of a material that is electrically conductive.

7. The vertically-laminated microdisplay panel of claim 1, wherein the bonding layer is formed of a ceramic material that is optically transparent and electrically conductive.

8. The vertically-laminated microdisplay panel of claim 1, wherein the back wafer is a silicon (Si) wafer.

9. The vertically-laminated microdisplay panel of claim 1, wherein an ohmic contact electrode is formed on at least one of an upper surface and a lower surface of each of the light-emitting portions.

10. The vertically-laminated microdisplay panel of claim 9, wherein the ohmic contact electrode is formed of a material that is optically transparent and electrically conductive.

11. A method of manufacturing a vertically-laminated microdisplay panel that does not require a color filter, the method comprising:
a preparing operation of preparing a plurality of front wafers which include a support wafer and a light-emitting portion and emit light having different colors, and preparing a back wafer having an upper surface on which a plurality of complementary metal oxide semiconductor (CMOS) electrode pads are arranged;
a stacking operation of repeating a process of bonding the front wafer onto the back wafer through bonding layers and then removing the support wafer and vertically stacking the plurality of light-emitting portions and the bonding layers on the back wafer;
an etching operation of etching the plurality of stacked light-emitting portions and bonding layers to be divided into preset units and arranging a plurality of light-emitting diode (LED) stacks on the plurality of CMOS electrode pads; and
a forming operation of forming a common electrode on the plurality of LED stacks,
wherein each of the plurality of LED stacks emits only light of a specific color by blocking light generated from at least one light-emitting portion of the plurality of light-emitting portions or forming a short path in at least one light-emitting portion of the plurality of light-emitting portions so that a current does not flow into and bypasses the light-emitting portion,
wherein the plurality of front wafers includes a first front wafer including the support wafer and a first light-emitting portion, a second front wafer including the support wafer and a second light-emitting portion, and a third front wafer including the support wafer and a third light-emitting portion, and
the plurality of LED stacks include a first LED stack configured to emit only light having a first color, a second LED stack configured to emit only light having a second color, and a third LED stack configured to emit only light having a third color,
wherein, in the etching operation, the short path is formed to pass through the third light-emitting portion and the second light-emitting portion at a portion in which the first LED stack is formed, and the short path is formed to pass through the third light-emitting portion at a portion in which the second LED stack is formed,
in the first LED stack, a current does not flow into and bypasses the third light-emitting portion and the second light-emitting portion through the short path, and
in the second LED stack, a current does not flow into and bypasses the third light-emitting portion through the short path.

12. (canceled)

13. The method of claim 11, wherein the stacking operation includes a first stacking operation of bonding the first front wafer onto the back wafer through a first bonding layer and then removing the support wafer to stack the first light-emitting portion on the back wafer, a second stacking operation of bonding the second front wafer onto the first light-emitting portion through a second bonding layer and then removing the support wafer to stack the second light-emitting portion on the first light-emitting portion, and a third stacking operation of bonding the third front wafer onto the second light-emitting portion through a third bonding layer and then removing the support wafer to stack the third light-emitting portion on the second light-emitting portion.

14. The method of claim 13, wherein, in the first stacking operation, after the support wafer is removed, a metal layer is formed on a portion of the first light-emitting portion,
in the second stacking operation, after the support wafer is removed, the metal layer is formed on a portion of the second light-emitting portion,
the second LED stack blocks light generated from the first light-emitting portion through the metal layer formed on the first light-emitting portion, and
the third LED stack blocks light generated from the second light-emitting portion and the first light-emitting portion through the metal layer formed on each of the second light-emitting portion and the first light-emitting portion.

15. The method of claim 14, wherein the metal layer includes a lower layer which has an absorptive property to block light generated from below and an upper layer which has a reflective property to reflect light generated from above.

16. (canceled)

17. The method of claim 11, wherein the short path is formed of a material that is electrically conductive.

18. The method of claim 11, wherein the bonding layer is formed of a ceramic material that is optically transparent and electrically conductive.

19. The method of claim 11, wherein the support wafer and the back wafer are silicon (Si) wafers.

20. The method of claim 11, wherein an ohmic contact electrode is formed on at least one of an upper surface and a lower surface of each of the light-emitting portions.

21. The method of claim 20, wherein the ohmic contact electrode is formed of a material that is optically transparent and electrically conductive.
